(19) United States
(12) Patent Application Publication
(10) Pub. No.: US 2026/0354063 A1
(43) Pub. Date: Nov. 5, 2026

(54) SUBSTRATE PROCESSING METHOD AND SUBSTRATE PROCESSING APPARATUS

(71) Applicant: Tokyo Electron Limited, Tokyo (JP)

(72) Inventors: Yohei YAMASHITA, Kikuchi-gun, Kumamoto (JP); Yohei YAMAWAKI, Kikuchi-gun, Kumamoto (JP)

(73) Assignee: Tokyo Electron Limited, Tokyo (JP)

(21) Appl. No.: 19/486,983

(22) PCT Filed: May 13, 2024
(86) PCT No.: PCT/JP2024/017598

§ 371 Date: Nov. 24, 2025

(30) Foreign Application Priority Data
May 25, 2023 (JP) 2023-086028

(51) Int. Cl. H10P 34/42; B23K 26/062; G02B 27/10; H10P 56/00; H10P 72/00

(52) U.S. Cl. CPC H10P 34/42; B23K 26/062; G02B 27/106; H10P 56/00; H10P 72/0428

(57) ABSTRACT

A substrate processing method of processing a substrate includes radiating a laser beam toward the substrate in a form of pulses. During the radiating of the laser beam, a branching element is inserted into or retracted from an optical path of the laser beam radiated from a laser head, depending on a previously set region in the substrate. At this time, a number of branches of the laser beam is switched to different values by independently inserting or retracting multiple branching elements into or from the optical path.

### TECHNICAL FIELD

The various aspects and embodiments described herein pertain generally to a substrate processing method and a substrate processing apparatus.

### BACKGROUND

Patent Document 1 discloses a substrate processing method in which a laser absorption layer of a combined substrate is irradiated with a laser beam in pulses. Patent Document 1 also discloses that by providing multiple laser radiation modules in a laser radiation device and irradiating the laser absorption layer with multiple laser beams, a processing time can be shortened and a throughput can be improved.

### Prior Art Document

Patent Document 1: International Publication No. 2021/131711

### DISCLOSURE OF THE INVENTION

### Problems to be Solved by the Invention

Exemplary embodiments provide a technique capable of efficiently performing laser radiation when processing a substrate by irradiating the substrate with a laser beam.

### Means for Solving the Problems

In an exemplary embodiment, a substrate processing method of processing a substrate includes radiating a laser beam toward the substrate in a form of pulses. During the radiating of the laser beam, a branching element is inserted into or retracted from an optical path of the laser beam radiated from a laser head, depending on a previously set region in the substrate.

### Effect of the Invention

According to the exemplary embodiments, it is possible to efficiently perform the laser radiation when processing the substrate by irradiating the substrate with the laser beam.

### BRIEF DESCRIPTION OF THE DRAWINGS

FIG. 1 is a side view schematically illustrating a structure of a combined wafer to be processed in a wafer processing system.

FIG. 2 is a plan view schematically illustrating a configuration of the wafer processing system.

FIG. 3 is a side view illustrating a schematic configuration of a laser radiation device.

FIG. 4 is a plan view illustrating the schematic configuration of the laser radiation device.

FIG. 5 is an explanatory diagram schematically illustrating a configuration of an optical system of the laser radiation device.

FIG. 6 is an explanatory diagram illustrating splitting laser beam by using one branching element.

FIG. 7 is an explanatory diagram illustrating splitting laser beam by using multiple branching elements.

FIG. 8 is an explanatory diagram illustrating laser radiation to the laser absorption layer.

FIG. 9A and FIG. 9B are explanatory diagrams illustrating separation of a first wafer from the laser absorption layer.

FIG. 10 is an explanatory diagram illustrating a pitch between radiation points of a laser beam.

FIG. 11 is an explanatory diagram illustrating laser radiation to a peripheral region.

FIG. 12 is an explanatory diagram illustrating another example of laser radiation to the peripheral region.

FIG. 13 is an explanatory diagram illustrating laser radiation to an intermediate region.

FIG. 14 is an explanatory diagram illustrating laser radiation to a central region.

FIG. 15A and FIG. 15B are explanatory diagrams illustrating a radial-direction pitch of a laser beam.

FIG. 16 is an explanatory diagram illustrating a relationship between a radial-direction position on the laser absorption layer and a radial-direction pitch of a laser beam.

FIG. 17 is an explanatory diagram illustrating laser radiation to the laser absorption layer.

### DETAILED DESCRIPTION

In a manufacturing process for a semiconductor device, a device layer formed on a surface of a first substrate is transferred to a second substrate. This transfer of the device layer is carried out by using a technique known as laser lift-off, in which a laser beam is radiated to a laser absorption layer formed between the first substrate and the device layer in a combined substrate, which is formed by bonding the first and second substrates together, thereby separating an interface between the first substrate and the laser absorption layer.

In this laser lift-off, the laser beam is radiated in pulses, while rotating the combined substrate and also moving a radiation position of the laser beam from an outer side to an inner side of the combined substrate in a radial direction. Here, to improve a throughput of a substrate processing, it has been proposed to split the laser beam into multiple beams and simultaneously radiate those multiple laser beams to different portions of the laser absorption layer.

To achieve uniform separation between the first substrate and the laser absorption layer across the surface of the substrate, it is desirable to maintain a constant pitch between radiation positions of the laser beam in the laser absorption layer. When maintaining such a constant pitch between the radiation positions of the laser beam, the circumferential velocity of the combined substrate varies depending on the position of the radiation position in the radial direction. Thus, the rotation speed of the combined substrate needs to be increased as the radiation position moves from the radially outer side toward the radially inner side. However, when the rotation speed of the combined substrate reaches its upper limit, the pitch between the radiation positions of the laser beam in a circumferential direction decreases as the radiation position of the laser beam moves toward the radially inner side, and the laser beam may be overlapped at a central portion of the laser absorption layer. In such a case, more energy than necessary is supplied to the laser absorption layer, which may result in damage to the device layer due to heat generated. Furthermore, the laser beam may not be absorbed by the laser absorption layer, and may reach the device layer, causing damage to the device layer.

In view of the foregoing, the present disclosure provides a technique that enables efficient radiation of a laser beam when processing a substrate by irradiating the substrate with the laser beam. Further, in the technique disclosed herein, the substrate and the laser absorption layer are separated by the radiation of the laser beam as stated above. Here, the term “separation” between the substrate and the laser absorption layer refers to a state in which the substrate is completely separated from the laser absorption layer and an adhesion force between them becomes zero, and also refers to a state in which the adhesion force between the substrate and the laser absorption layer remains but adhesion strength therebetween has been reduced to the extent that the substrate and the laser absorption layer can be easily separated from each other by using a transfer pad or separation device to be described later.

In the following description, the “separation” between the substrate and the laser absorption layer is assumed to refer to, for example, a state in which the substrate and the laser absorption layer are made into a state where they are not contact with each other (that is, the substrate is lifted up from the laser absorption layer) by using a transfer pad or the like to be described later.

Hereinafter, a wafer processing system equipped with a laser radiation device as a substrate processing apparatus according to an exemplary embodiment, and a wafer processing method as a substrate processing method will be explained with reference to the accompanying drawings. In the present specification and the accompanying drawings, parts having substantially the same functions and configurations will be assigned same reference numerals, and redundant descriptions thereof will be omitted.

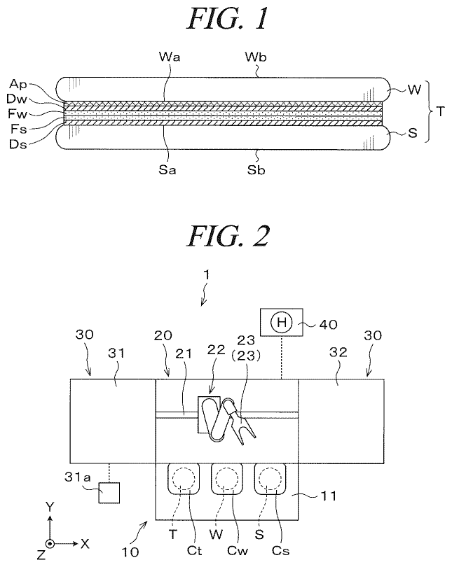

In the present exemplary embodiment, a wafer processing system 1 to be described below is configured to process a combined wafer T, which is a substrate in which a first wafer W and a second wafer S are bonded to each other as shown in FIG. 1. A wafer is an example of a substrate. Hereinafter, in the first wafer W, a surface to be bonded to the second wafer S will be referred to as a front surface Wa, and a surface opposite the front surface Wa will be referred to as a rear surface Wb. Likewise, in the second wafer S, a surface to be bonded to the first wafer W will be referred to as a front surface Sa, and a surface opposite the front surface Sa will be referred to as a rear surface Sb.

The first wafer W is a semiconductor wafer, such as a silicon substrate, and at least one film is stacked on the front surface Wa. Hereinafter, the film formed on the front surface Wa will be referred to as a “stacked film.” In the present exemplary embodiment, the stacked film includes a laser absorption layer Ap, a device layer Dw, and a bonding film Fw. The laser absorption layer Ap may be, by way of example, an oxide film (SiO₂ film), but is not limited thereto as long as it absorbs a laser beam L radiated from a laser radiation module 110 to be described later. The device layer Dw includes multiple devices. The bonding film Fw may be, by way of non-limiting example, an oxide film (THOX film, SiO₂ film, or TEOS film), a SiC film, a SiCN film, or an adhesive. In the wafer processing system 1 according to the present exemplary embodiment to be described below, the laser absorption layer Ap absorbs the laser beam L radiated from the laser radiation module 110, thereby causing separation at an interface between the first wafer W and the laser absorption layer Ap and transferring the device layer Dw to the second wafer S.

The second wafer S is a semiconductor wafer, such as, but not limited to, a silicon substrate, and a stacked film is formed on the front surface Sa. In this exemplary embodiment, the stacked film includes a device layer Ds and a bonding film Fs. The device layer Ds and bonding film Fs are the same as the device layer Dw and the bonding film Fw of the first wafer W, respectively. The combined wafer T is formed by bonding the bonding film Fw of the first wafer W to the bonding film Fs of the second wafer S.

The types of films, the number of layers, and the stacking order in the stacked films formed on the front surface Wa of the first wafer W and the front surface Sa of the second wafer S are not limited to the shown example.

By way example, in the stacked film formed on the front surface Wa of the first wafer W, the laser absorption layer Ap may be formed between the device layer Dw and the bonding film Fw. Alternatively, the device layer Dw and bonding film Fw may not be formed on the front surface Wa of the first wafer W. In this case, the laser absorption layer Ap is formed on the second wafer S, and the device layer Ds of the second wafer S is transferred to the first wafer W. Likewise, the device layer Ds and bonding film Fs may not be formed on the front surface Sa of the second wafer S.

Further, a separation-promoting film (not shown) for promoting separation between the first wafer W and the second wafer S may be formed between the first wafer W and the laser absorption layer Ap on the front surface Wa of the first wafer W, causing separation to take place at an interface between the separation-promoting film and the first wafer W. In this case, it is desirable to select the separation-promoting film such that an adhesion force between the separation-promoting film and the first wafer W (silicon, etc.) is at least smaller than an adhesion force between the separation-promoting film and the laser absorption layer Ap (oxide film).

As shown in FIG. 2, the wafer processing system 1 has a configuration in which a carry-in/out block 10, a transfer block 20, and a processing block 30 are connected as a single structure. The carry-in/out block 10 and the processing block 30 are arranged around the transfer block 20. Specifically, the carry-in/out block 10 is located on the negative Y-axis side of the transfer block 20. A laser radiation device 31 of the processing block 30, which will be elaborated later, is located on the negative X-axis side of the transfer block 20, and a cleaning device 32 (described later) is located on the positive X-axis side of the transfer block 20.

In the carry-in/out block 10, cassettes Ct, Cw, and Cs, each of which is capable of accommodating multiple combined wafers T, multiple first wafers W, and multiple second wafers S, respectively, are carried to/from, for example, the outside. The carry-in/out block 10 is provided with a cassette placement table 11. In the illustrated example, a plurality of cassettes, for example, the three cassettes Ct, Cw, and Cs, can be arranged on the cassette placement table 11 in a row along the X-axis direction. The number of the cassettes Ct, Cw, and Cs placed on the cassette placement table 11 is not limited to the example of the present exemplary embodiment, and may be selected as required.

The transfer block 20 is equipped with a wafer transfer device 22 configured to be movable on a transfer path 21 that extends in the X-axis direction. The wafer transfer device 22 has, for example, two transfer arms 23 for holding and transferring the combined wafer T, the first wafer W, and the second wafer S. Each transfer arm 23 is configured to be movable horizontally, vertically, around a horizontal axis, and around a vertical axis. Here, however, the configuration of the transfer arms 23 is not limited to the present exemplary embodiment and any of various other configurations may be appropriately adopted. The wafer transfer device 22 is configured to be able to transfer the combined wafer T, the first wafer W, and the second wafer S to the cassettes Ct, Cw, and Cs on the cassette placement table 11, the laser radiation device 31, and the cleaning device 32, which will be described later.

The processing block 30 has the laser radiation device 31 and the cleaning device 32.

The laser radiation device 31 irradiates the laser absorption layer Ap of the first wafer W with a laser beam (e.g., a CO₂ laser) to cause separation at the interface between the first wafer W and the laser absorption layer Ap, thereby transferring the device layer Dw formed on the front surface Wa of the first wafer W to the second wafer S. The laser radiation device 31 includes a control device 31a to be described later.

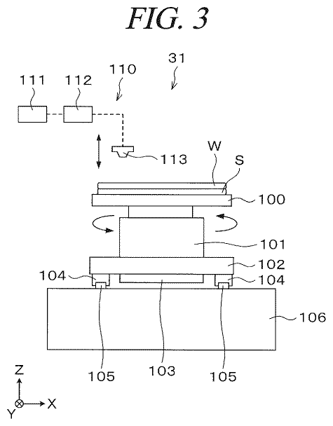

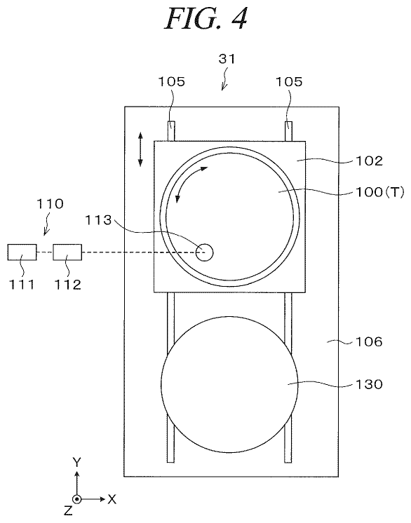

As depicted in FIG. 3 and FIG. 4, the laser radiation device 31 has a chuck 100 as a substrate holder, which is configured to hold the combined wafer T on a top surface thereof. The chuck 100 attracts and holds the entire rear surface Sb of the second wafer S. Alternatively, however, that the chuck 100 may attract and hold a portion of the rear surface Sb. The chuck 100 is provided with elevating pins (not shown) for supporting the combined wafer T from below and elevating it up and down. The elevating pins are configured to be movable up and down through a through hole (not shown) that is formed through the chuck 100.

The chuck 100 is supported by a slider table 102 with an air bearing 101 therebetween. A holder rotating mechanism 103 is provided on the bottom side of the slider table 102. The holder rotating mechanism 103 has, for example, a motor embedded therein as a power source. The chuck 100 is configured to be rotatable around a θ-axis (vertical axis) via the air bearing 101 by the holder rotating mechanism 103. The slider table 102 is configured to be movable along a rail 105, which is provided on a base 106 and extends in the Y-axis direction, by a holder moving mechanism 104 provided on the underside of the slider table 102. A driving source of the holder moving mechanism 104 is not particularly limited, but may be, by way of example, a linear motor.

The laser radiation module 110 is provided above the chuck 100. The laser radiation module 110 includes a laser head 111, an optical system 112, and a lens 113. The lens 113 may be configured to be movable up and down by an elevating mechanism (not shown).

The laser head 111 includes a laser oscillator (not shown) configured to emit a laser beam in the form of pulses. This laser beam is a so-called pulsed laser. In the present exemplary embodiment, the laser beam is a CO₂ laser beam, and the wavelength of this CO₂ laser beam is, for example, 8.9 μm to 11 μm. The laser head 111 may also include other components of the laser oscillator, such as an amplifier.

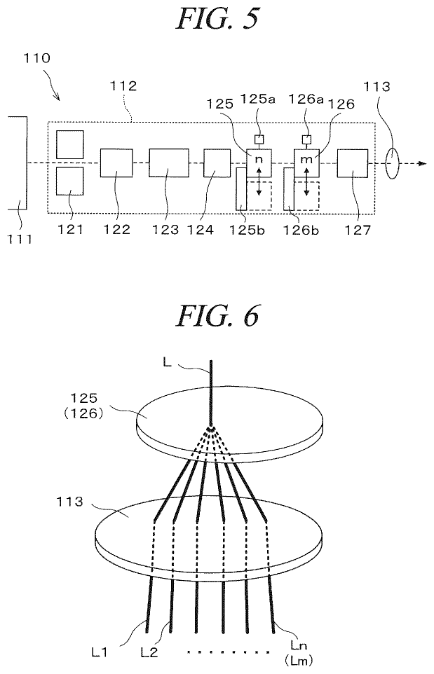

As shown in FIG. 5, the optical system 112 includes an iris 121, an expander 122, an isolator 123, an attenuator 124, a first branching element 125, a second branching element 126, and a galvanometer mirror 127.

The iris 121 cuts the laser beam radiated from the laser head 111 and shapes it into a required shape.

The expander 122 adjusts the diameter of the laser beam radiated from the laser head 111.

The isolator 123 suppresses reflection light from the combined wafer T, which is a target to which the laser beam is radiated, from returning back to the laser head 111.

The attenuator 124 attenuates the laser beam radiated from the laser head 111 to adjust an output thereof.

The galvanometer mirror 127 is configured to adjust the angle of incidence of the laser beam radiated from the laser head 111 onto the galvanometer mirror 127, allowing the laser beam to be scanned with respect to the combined wafer T. Here, scanning the laser beam L means moving the laser beam L radiated from the lens 113 of the laser radiation module 110 with respect to the laser absorption layer Ap.

As shown in FIG. 6, the first and second branching elements 125 and 126 branch the single laser beam L incident from the laser head 111 into multiple laser beams L whose radiation points are arranged in a line distribution (on a straight line). The branching elements may have any of various configurations, but may be, by way of non-limiting example, diffractive optical elements (DOE) or prisms. Although the number of branches (hereinafter simply referred to as a branch count) of the laser beam L by the first and second branching elements 125 and 126 is not particularly limited, it may differ between the first branching element 125 and the second branching element 126 in the present exemplary embodiment. In the following description, as shown in FIG. 5 and FIG. 6, the branch count of the first branching element 125 is denoted as n, and the branch count of the second branching element 126 is denoted as m (here, n and m are integers). Further, hereinafter, each of branched laser beams may be referred to as “branch laser beams L₁ to Lₙ” or “branch laser beams L₁ to Lₘ,” depending on the branch count.

The first and second branching elements 125 and 126 include rotating mechanisms 125a and 126a, respectively, and are configured to be rotatable about an axis with respect to an optical path of the laser beam. Accordingly, it is possible to control the arrangement of the radiation points of the multiple laser beams, which are arranged in the line distribution, in other words, control the direction in which the multiple radiation points are arranged on the laser absorption layer Ap to which the laser beams are radiated. Although the type and configuration of the rotating mechanisms 125a and 126a are not particularly limited, a piezoelectric motor, for example, may be employed.

In addition, in the present exemplary embodiment, the first and second branching elements 125 and 126 are equipped with moving mechanism 125b and 126b, respectively, and are configured to be inserted into or retracted from the optical path of the laser beam in the optical system 112, as illustrated in FIG. 5. Although the type and configuration of the moving mechanisms 125b and 126b are not particularly limited, a linear or rotary moving mechanism may be selected, and as a specific example, an actuator or slider mechanism may be used. In the optical system 112, by controlling the insertion or retraction of the first branching element 125 and the second branching element 126 with respect to the optical path, the branch count of the laser beam L outputted from the laser head 111 to be radiated to the combined wafer T can be controlled as required.

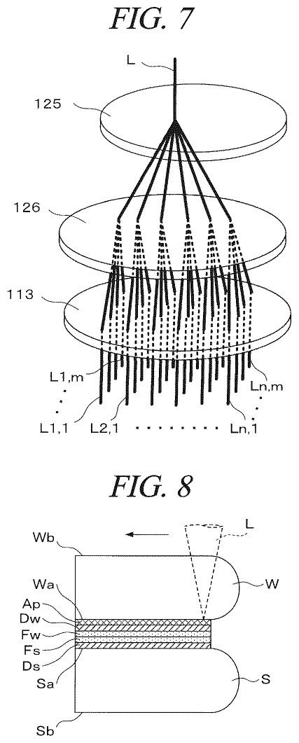

More specifically, by placing both the first branching element 125 and the second branching element 126 on the optical path, the single laser beam radiated from the laser head 111 can be branched into n×m branch laser beams arranged in a substantially rectangular pattern, as shown in FIG. 7.

By placing only the first branching element 125 on the optical path and removing the second branching element 126 from the optical path, the single laser beam radiated from the laser head 111 can be branched into n branch laser beams arranged in a line distribution, as shown in FIG. 6.

By placing only the second branching element 126 on the optical path and removing the first branching element 125 from the optical path, the single laser beam emitted from the laser head 111 can be branched into m branch laser beams arranged in a line distribution, as shown in FIG. 6.

Furthermore, by removing both the first branching element 125 and the second branching element 126 from the optical path, the single laser beam radiated from the laser head 111 can be radiated to the combined wafer T as a single laser beam without being branched.

In the illustrated example, the moving mechanisms 125b and 126b are provided for the first and second branching elements 125 and 126, respectively. In other words, although the multiple moving mechanisms are provided in the illustrated example, the optical system 112 may include only one moving mechanism shared by the first and second branching elements 125 and 126.

The lens 113 radiates the laser beam onto the combined wafer T held by the chuck 100. The laser beam emitted from the laser radiation module 110 penetrates the first wafer W and is radiated to the laser absorption layer Ap.

Reference is made back to FIG. 3 and FIG. 4.

A transfer pad 130 is further provided above the chuck 100. The transfer pad 130 is configured to be movable up and down by an elevating mechanism (not shown). The transfer pad 130 has an attraction surface for the first wafer W. The transfer pad 130 transfers the first wafer W between the chuck 100 and the transfer arm 23. Specifically, after the chuck 100 is moved to a position below the transfer pad 130 (a delivery position with respect to the transfer arm 23), the transfer pad 130 attracts and holds the rear surface Wb of the first wafer W and separates it from the second wafer S. Subsequently, the separated first wafer W is then handed over from the transfer pad 130 onto the transfer arm 23, and is carried out from the laser radiation device 31.

Reference is made back to FIG. 2.

The cleaning device 32 cleans the second wafer S and/or the first wafer W after their separation in the laser radiation device 31.

The wafer processing system 1 described above is provided with the control device 31a and at least one control device 40 as a controller. The control device 31a independently controls the operation of the laser radiation device 31. The control device 40 performs an overall control of a series of processes of a wafer processing in the wafer processing system 1. The control devices 31a and 40 process computer-executable instructions that cause the laser radiation device 31 and the wafer processing system 1, respectively, to perform various processes described in the present disclosure. The control devices 31a and 40 may be configured to control the individual components of the laser radiation device 31 and the wafer processing system 1, respectively, to perform various processes described in the present exemplary embodiment. In one embodiment, a part or the whole of the control device 31a may be included in the laser radiation device 31, and a part or the whole of the control device 40 may be included in the wafer processing system 1.

Each of the control devices 31a and 40 may include a processor, a memory device, and a communication interface. Each of the control devices 31a and 40 may be implemented by, for example, a computer. The processor may be configured to read from the memory device a program providing logic or routines that enable various control operations, and to execute the read program to perform the various control operations. This program may be previously stored in the memory device or retrieved via a medium when necessary. The retrieved program is stored in the memory device, and read from the memory device and executed by the processor. The medium may be a computer-readable recording medium H, or a communication line connected to the communication interface. In one embodiment, the memory device includes a program storage (not shown). The program storage stores a program for controlling a processing of the combined wafer T in the wafer processing system 1. Further, the program storage also stores a program for controlling an operation of a driving system such as the transfer devices and the various types of processing devices described above to carry out a wafer processing to be described below in the wafer processing system 1. The program may have been stored on the computer-readable recording medium H, and may be installed from the recording medium H into the control device 31a and the control device 40. The recording medium H may be transitory or non-transitory. The processor may be a central processing unit (CPU) or one or more circuits. The memory device may include a random access memory (RAM), a read only memory (ROM), a hard disk drive (HDD), a solid state drive (SSD), or a combination thereof. The communication interface may communicate between the laser radiation device 31 and the wafer processing system 1 via a communication line such as a local area network (LAN).

While the control device 31a and the control device 40 are installed separately for the laser radiation device 31 and the wafer processing system 1, respectively, the control devices 31a and 40 may be integrated. In other words, the operation of the laser radiation device 31 may be controlled by the control device 40.

Now, a wafer processing performed by using the wafer processing system 1 configured as described above will be explained. In the present exemplary embodiment, a first wafer W and a second wafer S are bonded to each other in a bonding apparatus (not shown) outside the wafer processing system 1 to form a combined wafer T in advance.

First, the cassette Ct containing the multiple combined wafers T is placed on the cassette placement table 11 of the carry-in/out block 10. Then, the combined wafer T is taken out from the cassette Ct by the wafer transfer device 22 and transferred to the laser radiation device 31. The combined wafer T held by the transfer arm 23 of the wafer transfer device 22 is then transferred to the chuck 100 of the laser radiation device 31.

In the laser radiation device 31, as shown in FIG. 8, the laser beam L (CO₂ laser beam) is radiated from the laser radiation module 110 in pulses toward the laser absorption layer Ap of the combined wafer T. At this time, the laser beam L penetrates the first wafer W from the rear surface Wb side thereof, and is then absorbed by the laser absorption layer Ap. At this time, by rotating the combined wafer T and moving the laser beam L from a radially outer side to a radially inner side, the entire surface of the laser absorption layer Ap is irradiated with the laser beam L. A specific method of radiating the laser beam L will be elaborated later.

The laser beam L absorbed by the laser absorption layer Ap is converted into heat at its radiation point according to its energy distribution. In other words, the temperature of the laser absorption layer Ap increases due to the radiation of the laser beam L, and the temperature at the interface between the first wafer W and the laser absorption layer Ap also increases due to heat diffusion. With the rise of the temperature at the interface between the first wafer W and the laser absorption layer Ap, the first wafer W is locally expanded (plastically deformed into a downwardly protruding shape toward the laser absorption layer Ap) according to this temperature distribution. As a result, the laser absorption layer Ap is pressed from above (the first wafer W side) as the first wafer W is expanded, and a stress exerted by this pressing causes separation at the interface between the laser absorption layer Ap and the first wafer W.

Thus, in the laser radiation device 31, by irradiating the entire surface of the laser absorption layer Ap with the laser beam L in pulses, separation at the entire interface between the laser absorption layer Ap and the first wafer W occurs due to a thermal effect caused by the radiation of the laser beam L, as described above.

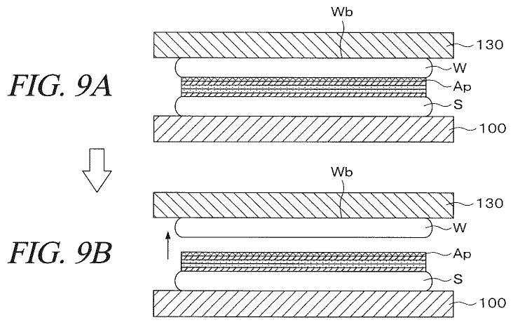

Next, as shown in FIG. 9A, the rear surface Wb of the first wafer W is attracted to and held by the transfer pad 130. Then, as shown in FIG. 9B, with the first wafer W attracted to and held by the transfer pad 130, the transfer pad 130 is raised to separate the first wafer W from the laser absorption layer Ap (second wafer S). Since the separation has occurred at the interface between the laser absorption layer Ap and the first wafer W due to the radiation of the laser beam L as described above, the first wafer W can be separated from the laser absorption layer Ap without applying a large load. Alternatively, the first wafer W may be separated by rotating the transfer pad 130 around a vertical axis

The separated first wafer W is then transferred from the transfer pad 130 onto the transfer arm 23 of the wafer transfer device 22, and transferred to the cassette Cw on the cassette placement table 11. Further, the first wafer W carried out from the laser radiation device 31 may be transferred to the cleaning device 32 before being transferred to the cassette Cw, where its front surface Wa, which is a separation surface, may be cleaned. In this case, the first wafer W may be transferred to the transfer arm 23 after its front and rear surfaces are inverted by the transfer pad 130.

Meanwhile, the second wafer S held on the chuck 100 is transferred by the transfer arm 23 to the cleaning device 32 to be cleaned.

Thereafter, the second wafer S, which has undergone all required processes, is transferred by the wafer transfer device 22 to the cassette Cs on the cassette placement table 11, which completes the series of processes of the wafer processing in the wafer processing system 1.

In the above-described exemplary embodiment, the first wafer W is completely separated from the laser absorption layer Ap (second wafer S) by the transfer pad 130 provided in the laser radiation device 31. However, instead of using the transfer pad 130, the separation of the laser absorption layer Ap (second wafer S) and the first wafer W may be performed in a separation device that is provided independently from the laser radiation device 31. In this case, the separation device (not shown) may be located on the positive Y-axis side of the transfer block 20 in the wafer processing system 1, for example.

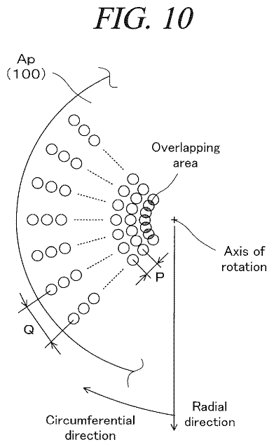

In the above-described laser radiation device 31, in order to improve a throughput of the wafer processing, the laser beam L is split into the multiple beams by using the branching elements as described above, and these multiple beams are radiated simultaneously. Furthermore, to achieve uniform separation between the first wafer W and the laser absorption layer Ap across the wafer surface, the wafer processing is controlled so that a pitch of the laser beam L radiated to the laser absorption layer Ap, more specifically, a pitch between radiation points on the laser absorption layer Ap, is constant across the wafer surface. Specifically, the pitch of the laser beam L in a radial direction of the laser absorption layer Ap (see FIG. 10; hereinafter sometimes referred to as “radial pitch P”) can be controlled by adjusting, for example, the movement amount of the chuck 100 (combined wafer T) in the Y-axis direction. The pitch of the laser beam L in a circumferential direction of the laser absorption layer Ap (see FIG. 10; hereinafter sometimes referred to as “circumferential pitch Q”) can be controlled by adjusting, for example, the rotation speed of the chuck 100 (combined wafer T). In order to maintain the circumferential pitch Q of the laser beam L constant, the rotation speed of the combined wafer T needs to be increased as the position of the radiation point moves from the radially outer side to the radially inner side (as approaching an axis of rotation).

However, when the rotation speed of the combined wafer T reaches an upper limit, the circumferential pitch Q gradually decreases as the position of the radiation point moves radially inwards. This can cause, particularly at a central region, the thermal effects of the multiple laser beams L to act on the same location in an overlapped manner, as shown by hatched portions in FIG. 10. When the laser beam L is radiated while being branched by the branching element, this concern is likely to become more conspicuous when the branch count is large and the distance between a radiation point located most inwards in the radial direction and a radiation point located most outwards in the radial direction is large. When the thermal effects are overlapped on the same location in this way, more energy than necessary is supplied to the laser absorption layer Ap, which can damage the device layer Dw due to heat and stress generated, or may result in a failure to separate the laser absorption layer Ap from the first wafer W properly.

Therefore, in the laser radiation device 31 according to the present exemplary embodiment, the pitch (particularly the circumferential pitch Q) between radiation points on the laser absorption layer Ap is appropriately adjusted by controlling the insertion or retraction of the first and second branching elements 125 and 126 into the optical path by the moving mechanisms 125b and 126b as well as the axial rotation of the first and second branching elements 125 and 126 with respect to the optical path by the rotating mechanisms 125a and 126a. In the present exemplary embodiment, the “appropriate pitch between the radiation points” refers to a pitch that suppresses overlapping of the thermal effects between at least adjacent radiation points and allows for appropriate separation between the first wafer W and the laser absorption layer Ap. Therefore, in the present exemplary embodiment, although it is desirable to control the pitch between the radiation points constant across the wafer surface, the pitch between the radiation points does not necessarily need to be constant, as long as the thermal effects between the adjacent radiation points do not overlap and the first wafer W and the laser absorption layer Ap can still be appropriately separated.

Below, details of the method of radiating the laser beam L (wafer processing method) in the laser radiation device 31 according to the present exemplary embodiment for controlling the pitch of the laser beam L radiated to the laser absorption layer Ap will be explained.

The following explanation will be given for an example where the branch count of the laser beam L by the first branching element 125 of the laser radiation module 110 is “n,” and the branch count of the laser beam L by the second branching element 126 is “m,” as described above.

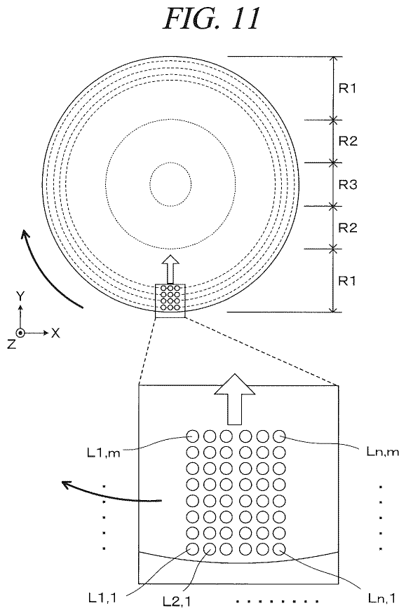

Further, in the following explanation, conditions for the radiation of the laser beam L to the combined wafer T will be described for three regions set in the laser absorption layer Ap (combined wafer T): a peripheral region R1, an intermediate region R2, and a central region R3 (see FIG. 11, etc.). The peripheral region R1 is a ring-shaped region located on the outermost side of the laser absorption layer Ap in the radial direction, which is the radiation target of the laser beam L. The central region R3 is a circular region located on the innermost side of the laser absorption layer Ap in the radial direction. The intermediate region R2 is a ring-shaped region located between the peripheral region R1 and the central region R3 in the laser absorption layer Ap in the radial direction. The peripheral region R1, the intermediate region R2, and the central region R3 are preset prior to the processing in the laser radiation device 31 based on various conditions, such as the pulse interval of the laser beam L and the rotation speed of the chuck 100.

In the present exemplary embodiment, by moving the laser beam L, which is radiated from the lens 113, from the radially outer side of the laser absorption layer Ap toward the radially inner side thereof, the laser beam L is radiated sequentially onto the peripheral region R1, the intermediate region R2, and the central region R3 in this order.

First, a method of radiating the laser beam L to the peripheral region R1 will be explained.

In the peripheral region R1 of the laser absorption layer Ap, by arranging both the first and second branching elements 125 and 126 on the optical path, the laser beam L from the laser head 111 is branched into multiple branch laser beams, in the present exemplary embodiment, n×m branch laser beams L_{1,1} to L_{n, m} in the laser radiation module 110, as shown in FIG. 11. These branch laser beams L_{1,1} to L_{n, m} are simultaneously radiated in the form of pulses. As illustrated in FIG. 7, the branch laser beams L_{1,1} to L_{n, m} are radiated to the laser absorption layer Ap in an approximately rectangular radiation point arrangement of n×m, when viewed from the top. At this time, the first and second branching elements 125 and 126 are rotated by the rotating mechanism 125a and 126a so that the long sides of the approximately rectangular shape (in the present exemplary embodiment, the arrangement direction of the branch laser beams L_{1,1} to L_{1,m}) are aligned along the radial direction of the laser absorption layer Ap, as shown in FIG. 11.

Furthermore, when radiating the laser beam L to the outer peripheral region R1, the rotation of the chuck 100 (combined wafer T) in the circumferential direction (360°) by the holder rotating mechanism 103 and the movement of the chuck 100 in the negative Y-axis direction by the holder moving mechanism 104 are alternately repeated. As the chuck 100 is rotated in 360° in the circumferential direction, the branch laser beams L_{1,1} to L_{n, m} are radiated to the outer peripheral region R1 in a ring shape concentric with the laser absorption layer Ap. By alternately repeating the radiation of the laser beam L in the ring shape and the movement of the chuck 100 in the negative Y-axis direction, the entire outer peripheral region R1 is irradiated with the branch laser beams L.

In this manner, in the laser radiation device 31 according to the exemplary embodiment, in the outer peripheral region R1 of the laser absorption layer Ap where the circumferential pitch Q between the radiation points is not affected by the relationship between the rotation speed of the chuck 100 (combined wafer T) and the pulse interval of the laser beam L (where the circumferential pitch Q can be appropriately maintained by controlling the rotation speed of the chuck 100), both of the two branching elements are disposed on the optical path. In this way, by branching the single laser beam L into the multiple branch laser beams L_{1,1} to L_{n, m} and simultaneously radiating them to the laser absorption layer Ap, a processing time required to irradiate the entire surface of the outer peripheral region R1 with the laser beam L can be shortened, thus improving a throughput.

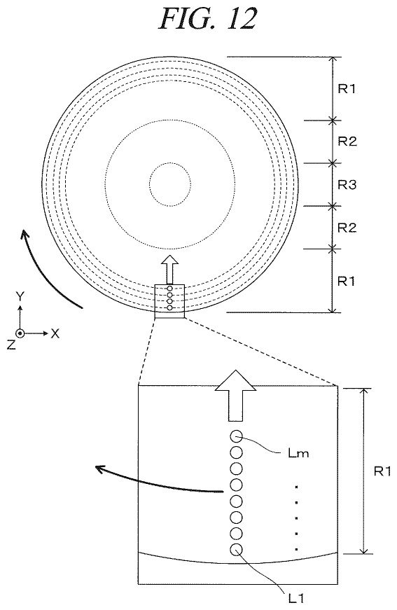

In the above exemplary embodiment, the laser beam L from the laser head 111 is radiated to the laser absorption layer Ap as the n×m branch laser beams L_{1,1} to L_{n,m}. However, if the output of the laser head 111 (light source) is not sufficient to ensure required energy per each of the branch laser beams L_{1,1} to L_{n,m}, or if the rotation speed of the chuck 100 (combined wafer T) is not sufficient to ensure a moving distance corresponding to a length of the short side of the approximately rectangular shape of n×m (in this exemplary embodiment, the arrangement direction of the branch laser beams L_{1,1} to L_{n,1}) within the pulse interval of the laser beam L, only the second branching element 126, which has a larger branch count, may be placed on the optical path, instead of arranging both branching elements on the optical path. In other words, as shown in FIG. 12, the laser beam L from the laser head 111 may be radiated to the laser absorption layer Ap as m branch laser beams L₁ to Lₘ arranged in a line distribution. In this case, the second branching element 126 is rotated around an optical axis by the rotating mechanism 126a so that multiple radiation points (extension direction of the line distribution) of the branch laser beams L₁ to Lₘ forming the line distribution are arranged along the radial direction of the laser absorption layer Ap. Even in this case, since the single laser beam L is branched into the multiple branch laser beams L₁ to Lₘ and simultaneously radiated to the laser absorption layer Ap, the processing time required to irradiate the entire outer peripheral region R1 with the laser beam L can be shortened, improving the throughput, and, also, the energy per each of the branch laser beams L₁ to Lₘ can be more easily secured.

Now, a method of radiating the laser beam L to the intermediate region R2 will be explained.

As the radiation point of the laser beam L is moved radially inwards from the peripheral region R1, it is possible to maintain an appropriate pitch between radiation points located on the outer side in the radial direction, whereas an appropriate pitch cannot be maintained between radiation points located on the inner side in the radial direction (processing limit), as illustrated in FIG. 10. This is because the radiation point of the branch laser beam L₁, which is located on the outermost side in the radial direction among the branch laser beams L₁ to Lₘ, and the radiation point of the branch laser beam Lₘ, which is located on the innermost side in the radial direction, are different in their distances from a rotation axis of the chuck 100 (combined wafer T), and therefore have different circumferential velocities at those positions.

Therefore, in the laser radiation device 31 according to the exemplary embodiment, the branch count of the laser beam L is changed in the intermediate region R2, where the radiation points of the branch laser beam Lₘ on the radially inner side cannot be properly spaced apart under the same radiation conditions as in the peripheral region R1 (where thermal effects of adjacent radiation points are overlapped).

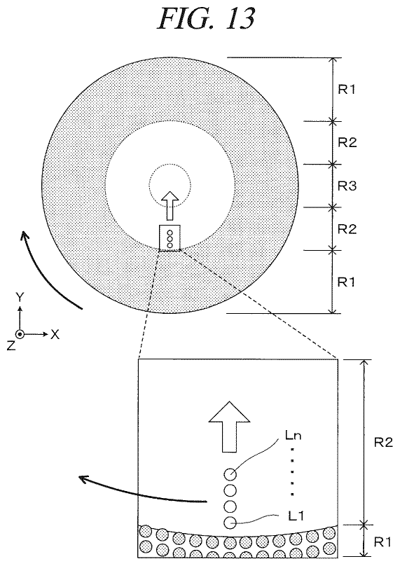

Specifically, in the intermediate region R2 of the laser absorption layer Ap, only the first branching element 125, which has a small branch count, is arranged on the optical path. This allows the laser beam L from the laser head 111 to be branched into multiple (n in this exemplary embodiment) branch laser beams L₁ to Lₙ in the laser radiation module 110, and these branch laser beams L₁ to Lₙ are simultaneously radiated in pulses. The branch laser beams L₁ to Lₙ are radiated to the laser absorption layer Ap in a linearly distributed radiation point arrangement when viewed from the top, as shown in FIG. 6. At this time, the first branching element 125 is rotated around the optical axis by the rotating mechanism 125a so that the linearly distributed radiation points are arranged along the radial direction of the laser absorption layer Ap, as shown in FIG. 13.

Furthermore, when radiating the laser beam L to the intermediate region R2, the rotation of the chuck 100 (combined wafer T) in the circumferential direction (360°) by the holder rotating mechanism 103 and the movement of the chuck 100 in the negative Y-axis direction by the holder moving mechanism 104 are alternately repeated. As the chuck 100 is rotated in 360° in the circumferential direction, the branch laser beam L is radiated to the intermediate region R2 in a ring shape concentric with the laser absorption layer Ap. Furthermore, by alternately repeating this radiation of the laser beam L in the ring shape and the movement of the chuck 100 in the negative Y-axis direction, the entire surface of the intermediate region R2 is irradiated with the branch laser beams L₁ to Lₙ.

In this way, in the laser radiation device 31 according to the present exemplary embodiment, in the intermediate region R2 where the appropriate pitch cannot be maintained between the radiation points on the radially inner side under the same radiation conditions as in the peripheral region R1, the branch count of the laser beam L from the laser head 111 is reduced. More specifically, the number of the radiation points arranged in the radial direction of the laser absorption layer Ap is reduced (from m to n in the present exemplary embodiment). As a result, in the intermediate region R2, the distance from the outermost radiation point to the innermost radiation point becomes shorter than that in the peripheral region R1. This reduces a difference in the circumferential velocity between the radiation points on the outer side and the radiation points on the inner side, thereby suppressing overlapping of thermal effects between the adjacent radiation points on the inner side.

Furthermore, in the intermediate region R2, by branching the single laser beam L into the multiple branch laser beams L₁ to Lₙ and simultaneously radiating them to the laser absorption layer Ap, the processing time can be shortened, at least compared to a case where the laser beam L is radiated without being branched. Therefore, the throughput can be improved.

Finally, a method of radiating the laser beam L to the central region R3 will be explained.

As the radiation point of the laser beam L is moved radially inwards from the intermediate region R2, the central region R3 is reached, where, under the same radiation conditions as in the intermediate region R2, it is no longer possible to maintain a proper pitch between radiation points located on the radially inner side (processing limit).

As a resolution, in the laser radiation device 31 of the present exemplary embodiment, the branch count of the laser beam Lis additionally changed in the central region R3, where, under the same radiation conditions as in the intermediate region R2, it is no longer possible to maintain a proper pitch between the radiation points on the radially inner side (where thermal effects of adjacent radiation points are overlapped).

Specifically, in the central region R3 of the laser absorption layer Ap, neither of the first and second branching elements 125 and 126 is placed on the optical path by the moving mechanisms 125b and 126b, and the laser beam L from the laser head 111 is not branched in the laser radiation module 110, but is instead radiated in pulses onto the laser absorption layer Ap as a single laser beam L.

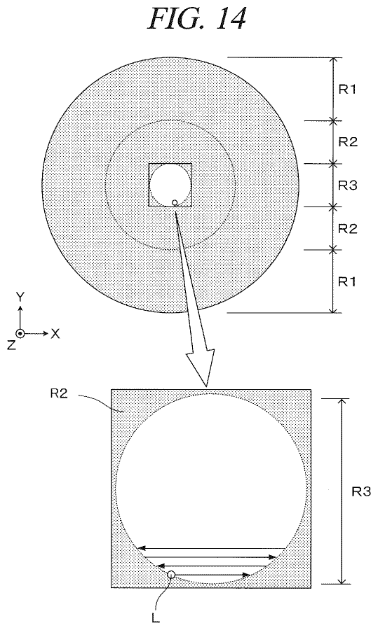

When radiating the laser beam L to the central region R3, the rotation of the chuck 100 is stopped. Then, the single laser beam Lis radiated in pulses from the laser radiation module 110. Furthermore, in the central region R3, scanning radiation of the laser beam L in the X-axis direction and movement of the chuck 100 (combined wafer T) in the Y-axis direction are alternately repeated, as illustrated in FIG. 14. Alternatively, the scanning radiation of the laser beam L in the X-axis direction and the movement of the chuck 100 in the negative Y-axis direction may be synchronized.

In this manner, in the laser radiation device 31 according to the present exemplary embodiment, the branch count of the laser beam L from the laser head 111 is reduced in the central region R3, where the proper pitch cannot be maintained between the radiation points on the radially inner side under the same radiation conditions as in the intermediate region R2. Furthermore, instead of radiating the laser beam L in a ring shape concentric with the laser absorption layer Ap by rotating the chuck 100 (combined wafer T), the laser beam Lis scan-radiated to the laser absorption layer Ap. This suppresses overlapping of thermal effects between adjacent radiation points even in the central region R3 on the radially inner side, where the circumferential velocity associated with the rotation of the chuck 100 (combined wafer T) is low.

In the above-described exemplary embodiment, the laser beam L is scan-radiated to the central region R3 in the state that the rotation of the chuck 100 is stopped. However, if the overlapping of the thermal effects between the adjacent radiation points can be suppressed, the laser beam L may be radiated in a ring shape concentric with the laser absorption layer Ap while rotating the chuck 100, the same as in the peripheral region R1 and the intermediate region R2.

As another example, with the rotation of the chuck 100 stopped, the radiation position of the laser beam L may be scanned in a spiral shape or in a ring shape concentric with the laser absorption layer Ap when viewed from the top by operating the galvanometer mirror 127.

As stated above, in the laser radiation device 31 according to the exemplary embodiment, the branch count of the laser beam L is switched by inserting or retracting the first and second branching elements 125 and 126 for each of the peripheral region R1, the intermediate region R2, and the central region R3 of the laser absorption layer Ap that are set in advance. In other words, the branch count of the laser beam L is switched by inserting or retracting the first and second branching elements 125 and 126 depending on the radial position on the laser absorption layer Ap to which the laser beam L is radiated.

In this way, by switching the branch count of the laser beam L for each preset region of the laser absorption layer Ap, the throughput can be significantly improved, as compared to a case where the entire surface of the laser absorption layer Ap is irradiated with the single laser beam L (where the laser beam L is not branched).

Furthermore, by inserting or retracting the first and second branching elements 125 and 126, the branch count of the laser beam L can be selected from “1,” “n,” “m,” and “n×m,” which significantly improves the degree of freedom in the process, as compared to a case where the branch count of the laser beam L is fixed. Specifically, as compared to the case where the branch count of the laser beam L is fixed, the laser beam L is allowed to approach closer to a further inner side of the laser absorption layer Ap when it is branched, thus significantly improving the throughput.

Besides, in the laser radiation device 31 according to the exemplary embodiment, the laser beam Lis branched by inserting or retracting the first and second branching elements 125 and 126 into or from the optical path of the laser beam L in the laser radiation module 110. This configuration allows the laser radiation module 110 to be made more compact compared to a configuration where a dedicated optical path for radiating the single laser beam Land a branching optical path for radiating the branch laser beams L are configured independently.

Moreover, when inserting or retracting the first and second branching elements by the moving mechanisms 125b and 126b in this manner, it is desirable to control the output of the laser beam L from the laser head 111 through the use of the attenuator 124 in association with this insertion or retraction.

To elaborate, when changing the branch count of the laser beam L as described above, the larger the branch count is, the greater the amount of energy required. In this case, there is a risk that the energy absorbed into the laser absorption layer Ap at each of the multiple radiation points may become non-uniform.

As a resolution, by controlling the output of the laser beam L through the use of the attenuator 124 in conjunction with the inserting/retracting operation of the first and second branching elements (branch count of the laser beam L), it is possible to appropriately maintain the processing energy constant at each radiation point.

In addition, in the above-described exemplary embodiment, the branch count of the laser beam L is controlled by providing the two branching elements (first and second branching elements 125 and 126) in the laser radiation module 110 and configuring them to be insertable into or retractable from the optical path.

However, the number of branching elements arranged in the laser radiation module 110 is not limited thereto, and three or more branching elements may be configured to be insertable into or retractable from the optical path. By providing three or more branching elements in the laser radiation module 110 and configuring these branching elements to be flexibly combined in this way, the degree of freedom in the process can be further improved. As a specific example, providing that the laser radiation module 110 is provided with a third branching element (not shown) in addition to the first and second branching elements 125 and 126 and a branch count by this third branching element is “k,” the branch count of the laser beam L can be selected as required from “1,” “n,” “m,” “k,” “n×m,” “n×k,” and“m×k.”

Additionally, the above explanation has been given for the method of adjusting the circumferential pitch Q of the radiation points in the laser absorption layer Ap. In addition to this, in the laser radiation device 31 according to the present exemplary embodiment, the radial pitch P of the laser beam L can be further adjusted from the pitch adjusted by the branching with the first and second branching elements 125 and 126 to achieve a shorter pitch.

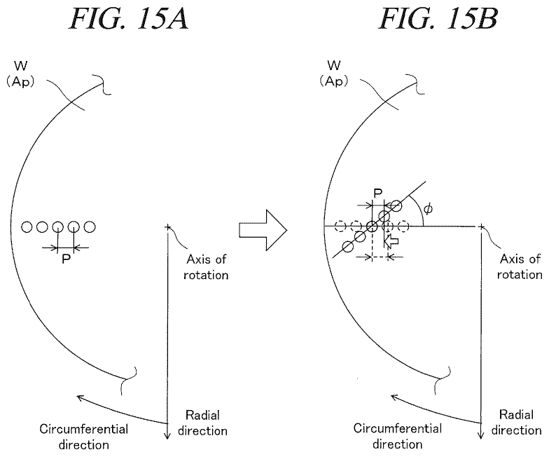

To elaborate, in the laser radiation device 31, it may be necessary to control the radial pitch P of the laser beam L. In this case, by rotating the extension direction of the array of the branch laser beam L in the line distribution from the radial direction of the first wafer W (see φ in the drawing), as illustrated in FIG. 15A and FIG. 15B, the radial pitch P of the laser beam L can be reduced without changing the branching pitch of the branch laser beams L in the branching element. The radial pitch P of the laser beam L can be precisely controlled by rotating the first and second branching elements 125 and 126 around the optical axis by using the rotating mechanism 125a and 126a. Therefore, the degree of freedom in the process can be improved.

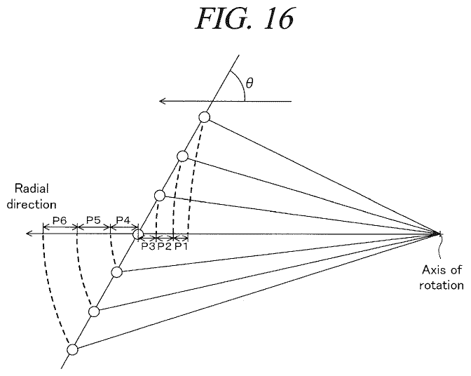

Meanwhile, when controlling the radial pitch P by rotating the first and second branching elements 125 and 126 around the optical axis in this manner, it has been observed that, as shown in FIG. 16, the radial pitch P becomes smaller at the same circumferential position depending on a radial position on the laser absorption layer Ap to which the laser beam L is radiated (see radial pitches P1 to P6 in the drawing: P1<P3<P6). In this case, it may not be possible to ensure an appropriate radial pitch P between the radiation point located on the innermost side in the radial direction and its adjacent radiation point. That is, in the example shown in FIG. 16, for example, the radial pitch P1 becomes smaller than an area affected by heat generated by laser radiation, which may result in overlapping of thermal effects between adjacent radiation points in the radial direction.

In view of this, in the laser radiation device 31 according to the present exemplary embodiment, the second branching element 126 with a large branch count of the laser beam L is placed on the optical path in the peripheral region R1 on the radially outer side of the laser absorption layer Ap, where the radial pitch P of the radiation points is not affected (where the radial pitch P can be appropriately maintained). In this way, by branching the single laser beam L into the multiple branch laser beams L and simultaneously radiating them to the laser absorption layer Ap, the processing time required to irradiate the entire peripheral region R1 with the laser beam L can be shortened, so that the throughput can be improved.

Further, in the intermediate region R2 where the radial pitch P cannot be appropriately maintained between the radiation points on the radially inner side under the same radiation conditions as in the peripheral region R1, the first branching element 125 with a small branch count of the laser beam L is placed on the optical path. This allows the multiple branch laser beams L to be simultaneously radiated to the laser absorption layer Ap to improve the throughput, while maintaining the radial pitch P appropriately to suppress overlapping of thermal effects between the adjacent radiation points.

In the laser radiation device 31 according to the exemplary embodiment, when simultaneously radiating the multiple branch laser beams to the laser absorption layer Ap, the arrangement direction of the radiation points of the laser beam L may be rotated with respect to the radial direction of the first wafer W. In this case, the radial pitch P of the laser beam L can be adjusted to a shorter interval than can be adjusted by the branching with the first and second branching elements 125 and 126. Therefore, the degree of freedom in the process can be further improved.

Furthermore, when radiating the laser beam L in the ring shape concentric with the laser absorption layer Ap as stated above, a processing end point of the laser beam L may be set with a slight gap in the circumferential direction from a processing start point. In this case, the laser beam L is not radiated to this gap, and the first wafer W and the laser absorption layer Ap are not separated in this portion. This makes separation more difficult to occur than in a portion irradiated with the laser beam L. If this gap is formed in alignment with the circumferential direction of the laser absorption layer Ap, proper separation may not be achieved at the corresponding circumferential position.

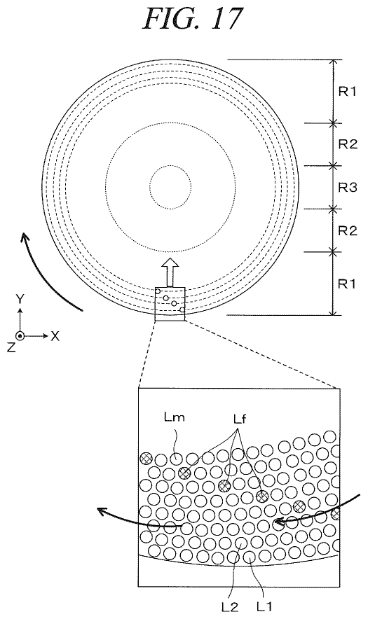

In this regard, if the arrangement direction of the radiation points of the laser beam L is rotated with respect to the radial direction of the first wafer W, as shown in FIG. 17, processing end points Lf in the circumferential direction when radiating the laser beam L in the concentric ring shape will be dispersed in the circumferential direction of the laser absorption layer Ap, making it less likely that a line due to a gap where the laser beam L is not radiated is formed in the radial direction.

In this way, by rotating the arrangement direction of the branch laser beams with respect to the radial direction of the first wafer W and dispersing the processing end points Lf in the circumferential direction, a problem regarding the ease of separation is less likely to occur as compared to a case where the processing end points Lf are consistent in the circumferential direction (when the gaps not irradiated with the laser beam L is arranged in a line distribution in the radial direction of the first wafer W).

Moreover, in the examples shown in FIG. 15A to FIG. 17, the branch count of the laser beam L is changed for the regions (the peripheral region R1, the intermediate region R2, and the central region R3) set prior to the wafer processing in the laser radiation device 31, and the first and second branching elements 125 and 126 are then rotated by the rotating mechanisms 125a and 126a to thereby rotate the arrangement direction of the radiation points of the laser beam L with respect to the radial direction of the first wafer W.

If, however, the pitch between the focal points of the laser beam L (particularly the radial pitch P) can be appropriately controlled solely by the rotation of the first and second branching elements 125 and 126 by the rotating mechanisms 125a and 126a without changing the branch count of the laser beam L, changing the branch count is not necessarily required. That is, during the wafer processing, the pitch between the focal points may be controlled solely by rotating the branching elements with the rotating mechanisms 125a and 126a, without inserting or retracting the branching elements into or from the optical path by using the moving mechanisms 125b and 126b.

In the above-described exemplary embodiment, the method of radiating the laser beam L according to the present disclosure is applied to laser lift-off in which the first wafer W is separated from the laser absorption layer Ap. However, the wafer processing to which the laser beam radiation method of the present disclosure is applicable is not limited thereto.

In a semiconductor device manufacturing process, by radiating a laser beam to an inside of a silicon substrate of a wafer, which has devices such as a plurality of electronic circuits formed on a surface thereof, along a plane direction thereof, a modification layer is formed, and by separating the wafer starting from this modification layer, the wafer is thinned. A YAG laser is used as the laser beam. The laser beam radiation method of the present disclosure can also be applied when forming such a modification layer. Furthermore, the laser beam radiation method described above can also be applied to various types of laser devices other than the laser radiation device described above. By way of example, it may be applied to techniques for modifying or planarizing the surface of the wafer.

In addition, in the above-described exemplary embodiment, the peripheral region R1, the intermediate region R2, and the central region R3 are determined in advance prior to the wafer processing in the laser radiation device 31. These regions may be determined prior to the wafer processing based on the processing limit (a threshold at which a radiation pitch can be controlled under certain radiation conditions for the laser beam L) that is calculated by the pulse interval or the rotation speed of the chuck 100 in the laser radiation device 31.

Furthermore, the number of the regions defined in the laser absorption layer Ap (combined wafer T) is not limited to three, but may be set to four or more based on, for example, the branch count of the laser beam L that is controllable by the laser radiation module 110.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

### EXPLANATION OF CODES

31: Laser radiation device
100: Chuck
110: Laser radiation module
111: Laser head
112: Optical system
125: First branching element
125b: Moving mechanism
126: Second branching element
126b: Moving mechanism
L: Laser beam
T: Combined wafer

1. A substrate processing method of processing a substrate, comprising:
radiating a laser beam toward the substrate in a form of pulses; and
during the radiating of the laser beam, inserting at least one branching element into or retracting the at least one branching element from an optical path of the laser beam radiated from a laser head, based on a region in the substrate.

2. The substrate processing method of claim 1,
wherein the at least one branching element includes multiple branching elements, and the multiple branching elements are inserted into or retracted from the optical path.

3. The substrate processing method of claim 2, further comprising:
switching a number of branches of the laser beam to different values by independently inserting or retracting the multiple branching elements into or from the optical path.

4. The substrate processing method of claim 3,
wherein each of the multiple branching elements branches the laser beam into multiple laser beams with different number of branches.

5. The substrate processing method of claim 2,
wherein each of the multiple branching elements branches the laser beam into multiple laser beams onto the substrate in a line distribution.

6. The substrate processing method of claim 1, further comprising:
controlling an output of the laser beam based on a number of branches of the laser beam radiated onto the substrate.

7. The substrate processing method of claim 1, further comprising:
rotating the at least one branching element around an axis of the optical path, and rotating an arrangement direction of radiation points of multiple laser beams, branched by the at least one branching element, with respect to a radial direction of the substrate.

8. The substrate processing method of claim 1,
wherein the region is previously set in correspondence with a position on the substrate in a radial direction, and
the region includes a peripheral region at an outer side in the radial direction of the substrate, a central region at an inner side in the radial direction of the substrate, and an intermediate region between the peripheral region and the central region in the radial direction of the substrate.

9. The substrate processing method of claim 1, further comprising:
determining the region based on a processing limit, which is determined by a rotation speed of the substrate and a pulse interval of the laser beam.

10. A substrate processing apparatus configured to process a substrate, comprising:
a substrate holder holding the substrate; and
a laser radiation module radiating a laser beam in a form of pulses onto the substrate held by the substrate holder,
wherein the laser radiation module comprises:
a laser head emitting the laser beam; and
an optical system having at least one branching element branching the laser beam from the laser head, and
the optical system comprises a moving mechanism inserting or retracting the at least one branching element into or from an optical path of the laser beam emitted from the laser head, and
the moving mechanism includes an actuator or a slider.

11. The substrate processing apparatus of claim 10,
wherein the at least one branching element of the optical system includes multiple branching elements.

12. The substrate processing apparatus of claim 11,
wherein the moving mechanism inserts or retracts each of the multiple branching elements into or from the optical path independently.

13. The substrate processing apparatus of claim 12,
wherein each of the multiple branching elements branches the laser beam into multiple laser beams with different number of branches.

14. The substrate processing apparatus of claim 12,
wherein each of the multiple branching elements branches the laser beam into multiple laser beams onto the substrate in a line distribution.

15. The substrate processing apparatus of claim 10, further comprising:
an attenuator controlling an output of the laser beam from the laser head based on a number of branches of the laser beam radiated onto the substrate.

16. The substrate processing apparatus of claim 10,
wherein the optical system further comprises a rotating mechanism configured to rotate the at least one branching element around an axis of the optical path, and
the rotating mechanism includes a motor.

17. The substrate processing apparatus of claim 16, further comprising:
controller circuitry configured to control an operation of the rotating mechanism, including:
executing a control of rotating an arrangement direction of radiation points of multiple laser beams, branched by the at least one branching element, with respect to a radial direction of the substrate by rotating the at least one branching element with the rotating mechanism.

18. The substrate processing apparatus of claim 10, further comprising:
controller circuitry configured to control an operation of the optical system, including:
executing a control of performing insertion or retraction of the at least one branching element into or from the optical path of the laser beam emitted from the laser head, based on a region of the substrate.

19. The substrate processing apparatus of claim 18,
wherein the region is previously set in correspondence with a position on the substrate in a radial direction, and
the region includes a peripheral region at an outer side in the radial direction of the substrate, a central region at an inner side in the radial direction of the substrate, and an intermediate region between the peripheral region and the central region in the radial direction of the substrate.

20. The substrate processing apparatus of claim 18, further comprising:
a holder rotating mechanism configured to rotate the substrate holder, the holder rotating mechanism including a motor,
wherein the region is determined based on a processing limit, which is determined by a rotation speed of the substrate and a pulse interval of the laser beam.
